(19) United States
(12) Patent Application Publication
(10) Pub. No.: US 2026/0282519 A1
(43) Pub. Date: Sep. 17, 2026

(54) SEMICONDUCTOR DEVICE

(71) Applicant: Minebea Power Semiconductor Device Inc., Hitachi-shi, Ibaraki (JP)

(72) Inventors: Masaki SHIRAISHI, Hitachi-shi (JP); Masaki NAMAI, Hitachi-shi (JP); Tomoyasu FURUKAWA, Tokyo (JP); Yujiro TAKEUCHI, Tokyo (JP)

(21) Appl. No.: 19/137,316

(22) PCT Filed: Sep. 27, 2023
(86) PCT No.: PCT/JP2023/035215

§ 371 Date: Jun. 10, 2025

(30) Foreign Application Priority Data
Dec. 12, 2022 (JP) 2022-197636

(51) Int. Cl. H10D 84/00; H10D 62/10

(52) U.S. Cl. CPC H10D 84/161; H10D 62/127

(57) ABSTRACT

Carriers are prevented from flowing into an IGBT region from a diode region so as to become concentrated in a boundary portion, thereby causing element breakage, during diode recovery. In a semiconductor device having an IGBT region, a diode region, and a wiring region in the same chip, the wiring region has a gate runner for supplying a gate potential to a trench gate electrode, a well layer having a deeper impurity diffusion depth than a trench, and a plurality of first contact regions that electrically connect the well layer and an emitter electrode. An area of the first contact region in a boundary portion vicinity near a boundary portion between the IGBT region and the diode region is greater than an area of the first contact region in a position far from the boundary portion vicinity.

### TECHNICAL FIELD

The present invention relates to a semiconductor device.

### BACKGROUND ART

A reverse-conducting insulated gate bipolar transistor (RC-IGBT) obtained by incorporating an IGBT and a diode within the same chip has an advantage in that a termination region can be shared between the IGBT and the diode, making it possible to reduce the chip size. In addition, since the IGBT and the diode operate at different timings, heat caused by loss occurring in one of the IGBT region and the diode region is dispersed to the other region, allowing the heat to be dissipated through the entire chip, and as a result, it is also possible to reduce thermal resistance.

On the other hand, in the RC-IGBT, carriers (holes) tend to flow from the diode region to the IGBT region at the time of diode recovery, which is the timing at which the IGBT turns ON and the diode changes from conduction to non-conduction, and as a result, a problem occurs in that the carriers (holes) become concentrated in a boundary portion between the diode region and the IGBT region, causing element breakage.

As a semiconductor device that reduces element breakage of this type, Patent Literature 1, for example, discloses a semiconductor device in which, in order to prevent breakage due to a recovery current concentrated in the vicinity of a triple point where an IGBT, a diode, and a gate runner intersect, either a partition trench is provided at a boundary portion, as shown in FIGS. 2, 5, and 6 of Patent Literature 1, or a contact region for hole extraction in a region near the boundary with the diode region is eliminated, as shown in FIG. 7 of Patent Literature 1.

### CITATION LIST

### Patent Literature

Patent Literature 1: Japanese Patent Application Publication No. 2009-94158

### SUMMARY OF INVENTION

### Technical Problem

However, with the method for providing a partition trench of Patent Literature 1, when a well layer that is deeper than the trench is provided, a problem occurs in that holes may flow into the boundary portion through the well layer and become concentrated. Moreover, if the partition trench is formed deeper than the well layer in order to solve this problem, a problem occurs in that either the trench in the IGBT region becomes too deep or the depth of the trench in the IGBT region and the depth of the partition trench must be changed.

Furthermore, the method for eliminating the contact region for hole extraction at the boundary with the diode region in Patent Literature 1 is assumed to be premised on the idea that by eliminating the contact area for hole extraction, holes will not gather, or will be less likely to gather. However, the possibility that holes will accumulate cannot be excluded even by eliminating the contact region for hole extraction.

The problem to be solved by the present invention is to provide a semiconductor device that has an IGBT region, a diode region, and a wiring region in the same chip, and that can prevent carriers from flowing to the IGBT region from the diode region during diode recovery so as to become concentrated in a boundary portion, thereby causing element breakage, even when a well layer that is deeper than a trench is formed in the wiring region.

### Solution to Problem

In order to solve the above problem, a semiconductor device of the present invention is, for example, a semiconductor device having an IGBT region, a diode region, and a wiring region in the same chip, wherein an IGBT in the IGBT region has an emitter electrode provided on a front surface side, a collector electrode provided on a rear surface side, and a trench gate electrode provided inside a trench, a diode in the diode region has a front surface electrode connected to the emitter electrode, and a rear surface electrode connected to the collector electrode, the wiring region has a gate runner for supplying a gate potential to the trench gate electrode, a well layer having a deeper impurity diffusion depth than the trench, and a plurality of first contact regions that electrically connect the well layer and the emitter electrode, and an area of the first contact region in a boundary portion vicinity near a boundary portion between the IGBT region and the diode region is greater than an area of the first contact region in a position far from the boundary portion vicinity.

### Advantageous Effects of Invention

According to the present invention, the area of the contact region near the boundary portion is large, and therefore the carrier extraction effect increases. As a result, it is possible to provide a semiconductor device that has an IGBT region, a diode region, and a wiring region in the same chip, and that can prevent carriers from flowing to the IGBT region from the diode region during diode recovery so as to become concentrated in a boundary portion, thereby causing element breakage, even when a well layer that is deeper than a trench is formed in the wiring region.

### BRIEF DESCRIPTION OF DRAWINGS

FIG. 1 is an upper view of a semiconductor device according to an embodiment.

FIG. 2 is an upper view of a semiconductor device according to embodiment 1, and an enlarged view of a portion E of FIG. 1.

FIG. 3 is an A-A′ cross-sectional view of FIG. 2.

FIG. 4 is a B-B′ cross-sectional view of FIG. 2.

FIG. 5 is a C-C′ cross-sectional view of FIG. 2.

FIG. 6 is a D-D′ cross-sectional view of FIG. 2.

FIG. 7 is an upper view of a semiconductor device according to embodiment 2, and an enlarged view of the portion E of FIG. 1.

### DESCRIPTION OF EMBODIMENTS

Embodiments of the present invention will be described below using the drawings. In each drawing and each embodiment, identical or similar constituent elements have been allocated identical reference symbols, and duplicate description thereof has been omitted.

### Embodiment 1

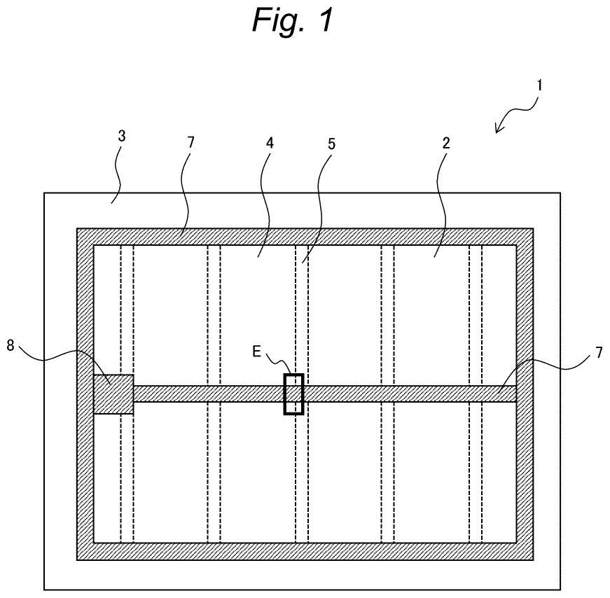

FIG. 1 is an upper view of a semiconductor device according to an embodiment. FIG. 1 is common to embodiment 1 and embodiment 2.

A semiconductor device 1 according to this embodiment has an IGBT region 4 and a diode region 5 in the same chip. The semiconductor device 1 has an active region 2 in which the IGBT region 4 and the diode region 5 are formed alternately, a termination region 3 surrounding the active region 2, a gate runner 7, which is a gate wire for supplying a gate potential, and a gate pad 8 that is connected to the outside and supplies the gate potential to the gate runner 7. Note that in the semiconductor device 1, an emitter electrode 21 of an IGBT and a front surface electrode 38 of a diode are provided on the front surface side in the active region 2, but these components are not shown in FIG. 1.

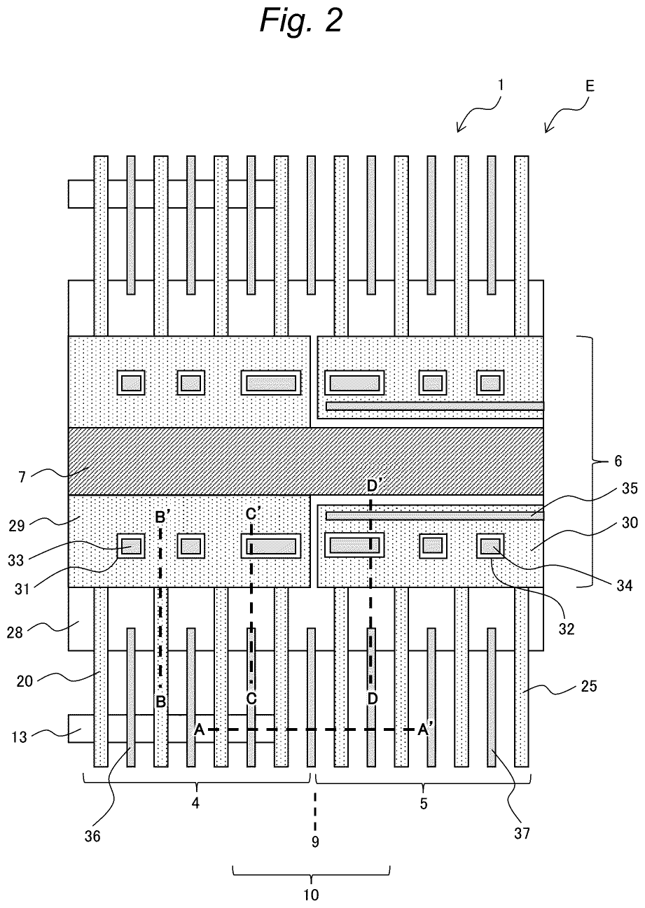

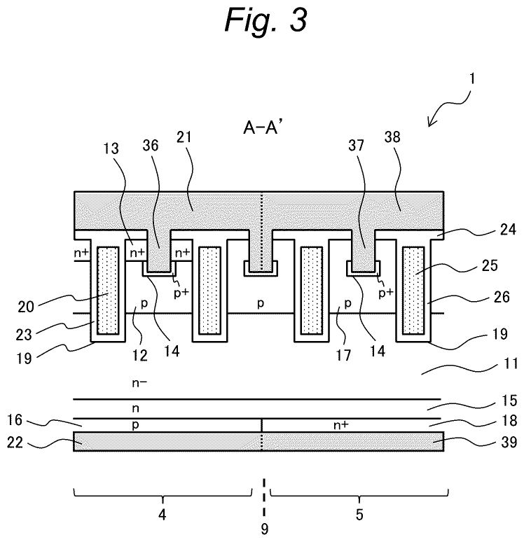

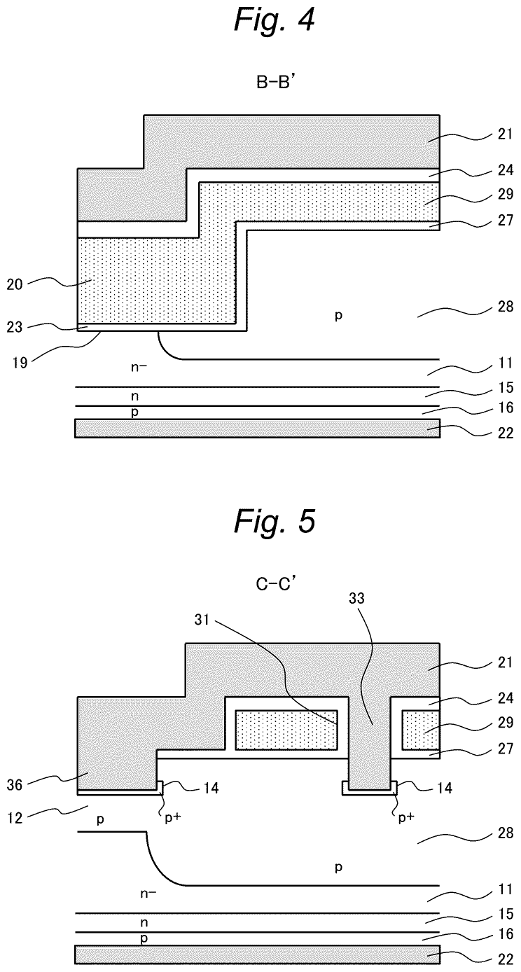

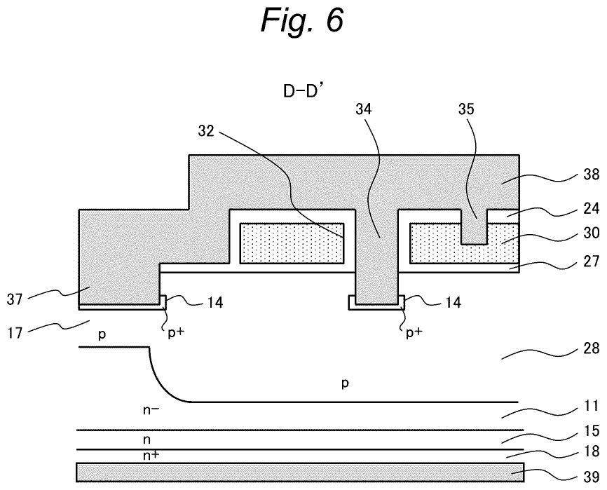

FIG. 2 is an upper view of the semiconductor device according to embodiment 1, and an enlarged view of a portion E of FIG. 1. FIG. 3 is an A-A′ cross-sectional view of FIG. 2, FIG. 4 is a B-B′ cross-sectional view of FIG. 2, FIG. 5 is a C-C′ cross-sectional view of FIG. 2, and FIG. 6 is a D-D′ cross-sectional view of FIG. 2. Note that the emitter electrode 21 and the front surface electrode 38 have been omitted likewise from FIG. 2.

As shown in FIGS. 2 and 3, the IGBT in the IGBT region 4 has the emitter electrode 21 provided on the front surface side, a collector electrode 22 provided on the rear surface side, and a trench gate electrode 20 provided inside a trench 19. The emitter electrode 21 and the collector electrode 22 are formed from metal, for example, and the trench gate electrode 20 is formed from polysilicon, for example.

The IGBT in the IGBT region 4 also includes a drift layer 11 formed from a semiconductor of a first conductivity type (in the example shown in FIG. 3, the n-type), a body layer 12 provided on the front surface side of the drift layer 11 and formed from a semiconductor of a second conductivity type (in the example shown in FIG. 3, the p-type), an emitter layer 13 provided on the front surface side of the body layer 12 and formed from a semiconductor of the first conductivity type, an interlayer insulating film 24 provided between the emitter layer 13 and trench gate electrode 20 and the emitter electrode 21, a buffer layer 15 provided on the rear surface side of the drift layer 11 and formed from a semiconductor of the first conductivity type, and a collector layer 16 provided between the buffer layer 15 and the collector electrode 22 and formed from a semiconductor of the second conductivity type. The emitter electrode 21 is connected to the emitter layer 13 in a fourth contact region 36, and is connected to the body layer 12 through the fourth contact region 36 and a contact layer 14 formed from a semiconductor of the second conductivity type.

The trench 19 has a depth that penetrates the body layer 12 and reaches the drift layer 11. A gate insulating film 23 is provided inside the trench 19 so as to surround the trench gate electrode 20.

The diode in the diode region 5 includes the front surface electrode 38 connected to the emitter electrode 21, and a rear surface electrode 39 connected to the collector electrode 22. The front surface electrode 38 is formed integrally with the emitter electrode 21, and the rear surface electrode 39 is formed integrally with the collector electrode 22.

The diode in the diode region 5 also includes the drift layer 11, a front surface-side semiconductor layer 17 provided on the front surface side of the drift layer 11 and formed from a semiconductor of the second conductivity type, the interlayer insulating film 24, the buffer layer 15, and a rear surface-side semiconductor layer 18 provided between the buffer layer 15 and the rear surface electrode 39 and formed from a semiconductor of the first conductivity type. Note that the diode region 5 may also be configured such that the buffer layer 15 is absent therefrom. The front surface electrode 38 is connected to the front surface-side semiconductor layer 17 through a fifth contact region 37 and the contact layer 14.

A trench electrode 25 formed from polysilicon, for example, and an in-trench insulating film 26 formed to surround the trench electrode 25 are provided in the trench 19 of the diode region 5.

As shown in FIGS. 2, 4, and 5, the wiring region 6 includes the gate runner 7 for supplying the gate potential to the trench gate electrode 20, a well layer 28 having a deeper impurity diffusion depth than the trench 19, and a plurality of first contact regions 33 electrically connecting the well layer 28 and the emitter electrode 21. Carriers (holes) can be extracted through the first contact region 33 provided on the IGBT region 4 side of the wiring region 6. Note that the well layer 28 is formed from a semiconductor of the second conductivity type and becomes shallower midway so as to be connected to the body layer 12 and the front surface-side semiconductor layer 17 (see FIG. 6). Note that the first contact regions 33 are connected to the well layer 28 through the contact layer 14. An insulating film 27 is formed on the front surface of the well layer 28, and is connected to the gate insulating film 23 and the in-trench insulating film 26.

The wiring region 6 also has a first lead-out wire 29 that is connected to the gate runner 7 and the trench gate electrode 20 in order to lead out a wire from the trench gate electrode 20 to the outside of the trench 19. The first lead-out wire 29 is formed from polysilicon, for example. The first lead-out wire 29 is also formed in a position overlapping the gate runner 7, and is connected to the gate runner 7 through a contact hole (not shown) formed in the interlayer insulating film 24. The first lead-out wire 29 has first openings 31 that are larger than the first contact regions 33 in positions corresponding to the first contact regions 33. Thus, the emitter electrode 21 can be connected to the well layer 28 by the first contact region 33 while avoiding the first lead-out wire 29.

As shown in FIGS. 2 and 6, the wiring region 6 has a plurality of second contact regions 34 electrically connecting the well layer 28 and the front surface electrode 38. Carriers (holes) can be extracted through the second contact region 34 provided on the diode region 5 side of the wiring region 6. Note that the second contact regions 34 are connected to the well layer 28 through the contact layer 14.

The wiring region 6 also has a second lead-out wire 30 that is connected to the trench electrode 25 in order to lead out a wire from the trench electrode 25 to the outside of the trench 19. The second lead-out wire 30 is formed from polysilicon, for example. The second lead-out wire 30 has second openings 32 that are larger than the second contact regions 34 in positions corresponding to the second contact regions 34. Thus, the front surface electrode 38 can be connected to the well layer 28 by the second contact regions 34 while avoiding the second lead-out wire 30.

The wiring region 6 has a third contact region 35 electrically connecting the second lead-out wire 30 and the front surface electrode 38 in a different position from the second contact regions 34. Thus, while forming the first contact regions 33, the second contact regions 34, and the third contact region 35 together, the trench gate electrode 20 can be connected to the gate runner 7 through the first lead-out wire 29, and the trench electrode 25 can be connected to the emitter electrode 21 through the second lead-out wire 30 and the front surface electrode 38.

In the semiconductor device 1 of embodiment 1, as shown in FIG. 2, the area of the first contact region 33 in a boundary portion vicinity 10 near a boundary portion 9 between the IGBT region 4 and the diode region 5 is set to be greater than the area of the first contact region 33 in a position far from the boundary portion vicinity 10. Thus, the carrier (hole) extraction effect is increased in the boundary portion vicinity 10, where carriers (holes) from the diode region 5 tend to concentrate.

Further, since the area of only the first contact region 33 in the boundary portion vicinity 10 is increased, rather than increasing the areas of all of the first contact regions 33, the first openings 31 of the first lead-out wire 29 need not be increased in size in positions far from the boundary portion vicinity 10, and as a result, an increase in the amount of gate resistance due to the increase in the area of the first contact region 33 can be reduced.

Furthermore, in the semiconductor device 1 of the embodiment 1, as shown in FIG. 2, the area of the second contact region 34 in the boundary portion vicinity 10 is also set to be larger than the area of the second contact region 34 in a position far from the boundary portion vicinity 10. As a result, the carrier (hole) extraction effect in the boundary portion vicinity 10 is increased likewise on the diode region 5 side.

Note that in embodiment 1, a case in which the first conductivity type is the n-type and the second conductivity type is the p-type was described as an example. In this case, the front surface electrode 38 is an anode electrode, the rear surface electrode 39 is a cathode electrode, the front surface-side semiconductor layer 17 is an anode layer, and the rear surface-side semiconductor layer 18 is a cathode layer. Further, the carriers are holes. However, the present invention is not limited thereto, and the first conductivity type may be the p-type and the second conductivity type may be the n-type. In this case, the anode and the cathode are reversed, and electrons rather than holes serve as the carriers.

Furthermore, as regards the impurity concentrations, for example, the drift layer 11 is shown to be of the low-concentration n− type, the emitter layer 13 is shown to be of the high-concentration n+ type, the contact layer 14 is shown to be of the high-concentration p+ type, and the rear surface-side semiconductor layer 18 is shown to be of the high-concentration n+ type, but the present invention is not limited thereto, and the impurity concentrations may be modified as appropriate within a range in which an operation can be performed.

As described above, according to the semiconductor device 1 of embodiment 1, the area of the contact region near the boundary portion is large, and therefore the carrier extraction effect increases. Thus, in a semiconductor device having an IGBT region, a diode region, and a wiring region in the same chip, it is possible to prevent carriers from flowing to the IGBT region from the diode region during diode recovery so as to become concentrated in the boundary portion, thereby causing element breakage, even when a well layer that is deeper than the trench is formed in the wiring region.

### Embodiment 2

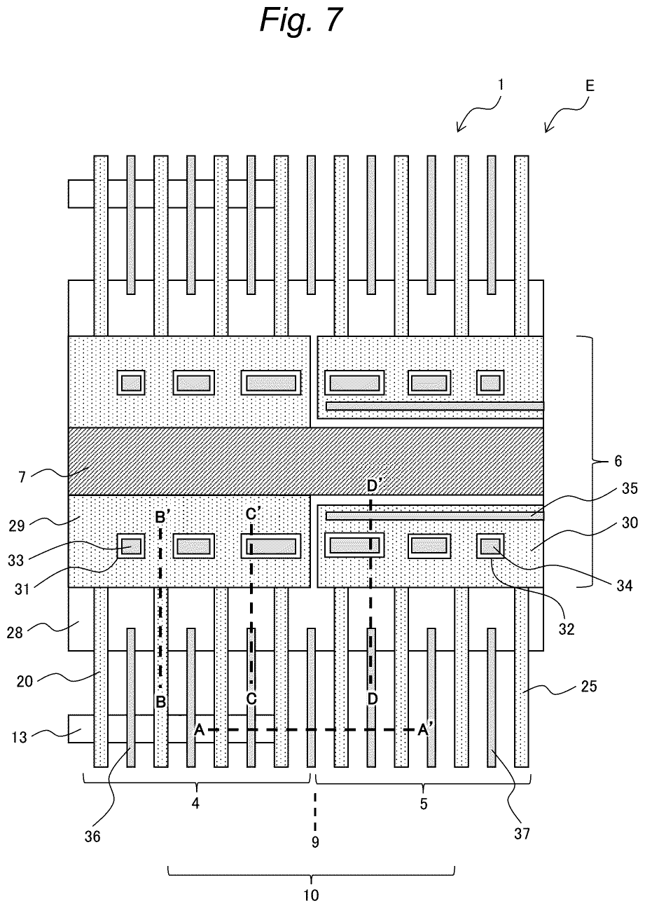

FIG. 7 is an upper view of a semiconductor device according to embodiment 2, and an enlarged view of the portion E of FIG. 1.

Embodiment 2 is a modification of embodiment 1 in which the areas of the first contact region 33 and the second contact region 34 are different from embodiment 1.

In the semiconductor device 1 of embodiment 2, as shown in FIG. 7, the area of the first contact region 33 in the boundary portion vicinity 10 gradually increases toward the boundary portion 9. Similarly, the area of the second contact region 34 in the boundary portion vicinity 10 also gradually increases toward the boundary portion 9.

According to embodiment 2, the carrier extraction effect can be increased while reducing the increase in the amount of gate resistance relative to embodiment 1. All other configurations and effects are the same as those of embodiment 1.

Although embodiments of the present invention were described above, the present invention is not limited to the configurations described in the embodiments, and various modifications are possible within the scope of the technical concept of the present invention. In addition, some or all of the configurations described in the embodiments may be applied in combination.

### REFERENCE SIGNS LIST

1 Semiconductor device
2 Active region
3 Termination region
4 IGBT region
5 Diode region
6 Wiring region
7 Gate runner
8 Gate pad
9 Boundary portion
10 Boundary portion vicinity
11 Drift layer
12 Body layer
13 Emitter layer
14 Contact layer
15 Buffer layer
16 Collector layer
17 Front surface-side semiconductor layer
18 Rear surface-side semiconductor layer
19 Trench
20 Trench gate electrode
21 Emitter electrode
22 Collector electrode
23 Gate insulating film
24 Interlayer insulating film
25 Trench electrode
26 In-trench insulating film
27 Insulating film
28 Well layer
29 First lead-out wire
30 Second lead-out wire
31 First opening
32 Second opening
33 First contact region
34 Second contact region
35 Third contact region
36 Fourth contact region
37 Fifth contact region
38 Front surface electrode
39 Rear surface electrode

1. A semiconductor device having an IGBT region, a diode region, and a wiring region in the same chip,
wherein an IGBT in the IGBT region has an emitter electrode provided on a front surface side, a collector electrode provided on a rear surface side, and a trench gate electrode provided inside a trench,
a diode in the diode region has a front surface electrode connected to the emitter electrode, and a rear surface electrode connected to the collector electrode,
the wiring region has a gate runner for supplying a gate potential to the trench gate electrode, a well layer having a deeper impurity diffusion depth than the trench, and a plurality of first contact regions that electrically connect the well layer and the emitter electrode, and
an area of the first contact region in a boundary portion vicinity near a boundary portion between the IGBT region and the diode region is greater than an area of the first contact region in a position far from the boundary portion vicinity.

2. The semiconductor device according to claim 1,
wherein the area of the first contact region in the boundary portion vicinity gradually increases toward the boundary portion.

3. The semiconductor device according to claim 1,
wherein the wiring region includes a first lead-out wire that is connected to the gate runner and the trench gate electrode in order to lead out a wire from the trench gate electrode to the outside of the trench, and
the first lead-out wire has first openings that are larger than the first contact regions in positions corresponding to the first contact regions.

4. The semiconductor device according to claim 1,
wherein the wiring region has a plurality of second contact regions electrically connecting the well layer and the front surface electrode, and
an area of the second contact region in the boundary portion vicinity is larger than an area of the second contact region in a position far from the boundary portion vicinity.

5. The semiconductor device according to claim 4,
wherein the area of the second contact region in the boundary portion vicinity gradually increases toward the boundary portion.

6. The semiconductor device according to claim 4,
wherein the diode region has a trench electrode provided inside the trench,
the wiring region has a second lead-out wire that is connected to the trench electrode in order to lead out a wire from the trench electrode to the outside of the trench, and a third contact region electrically connecting the second lead-out wire and the front surface electrode in a different position from the second contact regions, and
the second lead-out wire has second openings that are larger than the second contact regions in positions corresponding to the second contact regions.
